(19) United States
(12) Patent Application Publication
(10) Pub. No.: US 2003/0003748 A1
(43) Pub. Date: Jan. 2, 2003

(54) Method of eliminating notching when anisotropically etching small linewidth openings in silicon on insulator

(76) Inventors: Anisul Khan, Sunnyvale, CA (US); Ajay Kumar, Sunnyvale, CA (US); Yiqiong Wang, San Marino, CA (US); Jin-Yuan Chen, Bountiful, UT (US); Arthur H. Sato, San Jose, CA (US)

Correspondence Address: APPLIED MATERIALS, INC., 2881 SCOTT BLVD. M/S 2061, SANTA CLARA, CA, 95050, US

(21) Appl. No.: 09/866,313

(22) Filed: May 24, 2001

(51) Int. Cl. H01L 21/311

(52) U.S. Cl. 438/694

(57) ABSTRACT

We have found that by applying pulsed bias power to a substrate support electrode in an etch chamber, anisotropic etching of silicon over an insulator layer can be carried out with a minimum of notching at the silicon-insulator interface and with improved uniformity of etching across the substrate.

This invention relates to a method of anisotropically etching high aspect ratio openings in silicon. More particularly, this invention relates to a method of eliminating notching at the interface of silicon and an insulator.

### BACKGROUND OF THE INVENTION

When etching straight walled high aspect ratio openings in silicon over an insulator layer, such as silicon oxide, using fluorinated etchants, e.g., a mixture of sulfur hexafluoride and oxygen, a severe notch forms at the silicon-silicon oxide interface. This indicates some isotropic etching occurs at the interface. Further, this notching becomes more pronounced as the line width of the openings becomes smaller. For example, 10 micron wide linewidth openings have a small notch, whereas notching is worse as line widths are reduced to five microns, 2 microns and 1 micron. This notching occurs across the substrate, but is greater at the edge than at the center of the substrate.

FIG. 1 illustrates the notching that occurs at the bottom of openings of varying width, both at the center and at the edge of a substrate. Notching is very pronounced at 1, 2, and 5 micron linewidths, both at the center and at the edge of the substrate, and is still apparent even at 10 micron linewidths. The etch was carried out by first depositing a fluorinated polymer to protect the photoresist pattern, using a fluorocarbon or hydrofluorocarbon gas, such as C₄F₈. The deposition step was run at 18 mTorr pressure using 700 watts of power and a gas flow of 140 sccm for 5 seconds in a plasma etch chamber.

The etch step was carried out under the same reaction conditions of pressure and power as the deposition step, except using a bias power to the substrate support of 7 watts, using an etch gas mixture of 150 sccm of SF₆ and 15 sccm of oxygen for 10 seconds.

An overetch step was then carried out, by again depositing a protective polymer layer, then increasing the pressure to 25 mTorr and using 130 sccm of C₄F₈ for five seconds, without bias power. The overetch was then carried out using 9 watts of bias power, and 100 sccm of SF₆ for 12 minutes.

The average depth of the trench was about 14.9 microns; the average etch rate was about 1.36 microns/min; and the average selectivity between the photoresist mask and silicon was 17.8. Notch measurements in microns were taken at the bottom of the trenches, as set forth below:

| | Notch width, center | Notch width, edge |
|---|---|---|
| 1 micron line | 0.84 | 1.04 |
| 2 micron line | 1.62 | 2.00 |
| 5 micron line | 1.44 | * |
| 10 micron line | <0.2 | >0.2 |
| 100 micron line | >0.2 | <0.2 |

*line etched through the silicon at the bottom of the trench

Thus at small line widths, the notch was more than one-half of the line width; when overetching the 5 micron line, notching was so severe that the silicon between the openings peeled off. FIG. 1 includes a series of photomicrographs illustrating the severe notching at various linewidth. both at the center and at the edge of the substrate. Thus a method of reducing the notching at the bottom of a silicon trench over an insulator layer would be highly desirable.

### SUMMARY OF THE INVENTION

We have found that notching can be reduced or eliminated by using pulsed bias power during the main etch step. Further improvements can be made by using pulsed bias power during the overetch step as well. In addition, the elimination of oxygen gas during the main etch step further reduced notching at the silicon/silicon oxide interface.

### BRIEF DESCRIPTION OF THE DRAWING

FIG. 1 includes photomicrographs of etched profiles for various linewidths at the center and at the edge of the substrate after etching according to a method of the prior art.

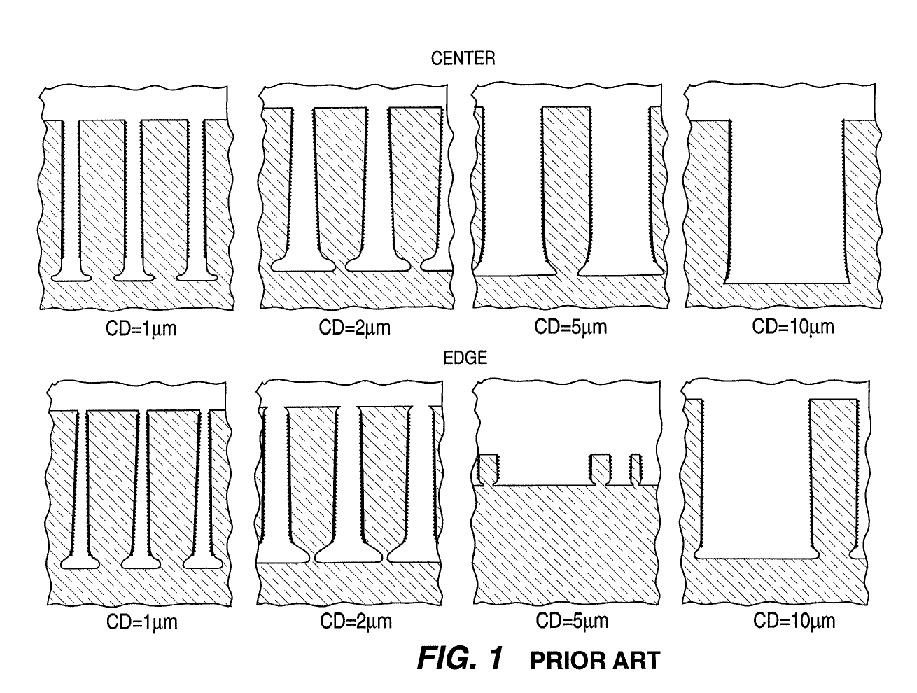

FIG. 2 is a cross sectional view of a plasma etch chamber that can be used to carry out the present etch method.

FIG. 3 shows photomicrographs of etched profiles for various linewidths at the center and edge of a substrate after etching according to the present invention.

FIG. 4 shows photomicrographs of etched profiles for various linewidths at the center and edge of a substrate after etching using another embodiment of the present invention.

FIG. 5 shows photomicrographs of etched profiles for various linewidths at the center and edge of a substrate after etching using still another embodiment of the present invention.

FIG. 6 shows photomicrographs of etched profiles for various linewidths at the center and edge of a substrate after etching using still another embodiment of the present invention.

### DETAILED DESCRIPTION OF THE INVENTION

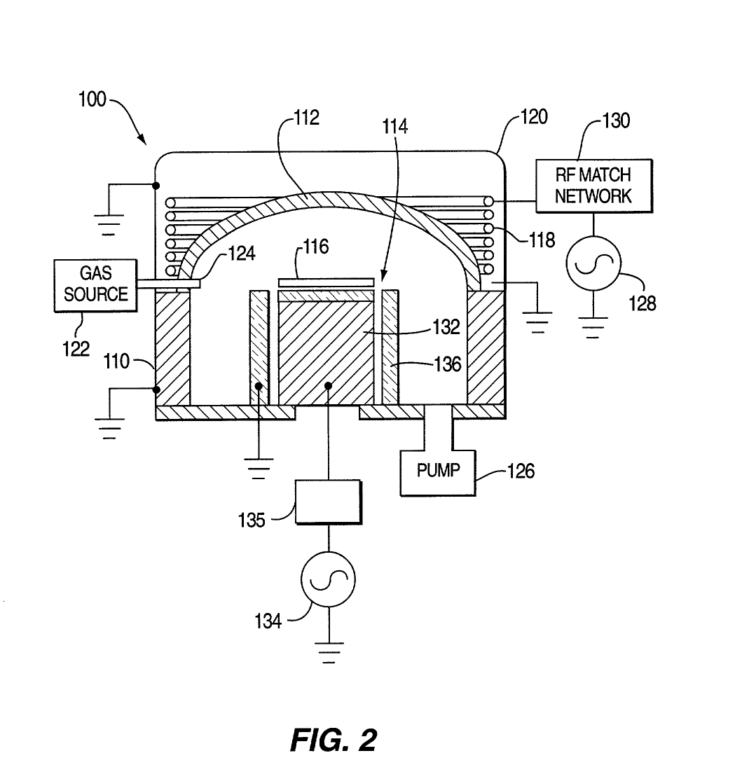

A suitable chamber for carrying out the trench etching described herein is shown in FIG. 2. This chamber is referred to as a decoupled plasma source (DPS) chamber.

The inductively coupled RF plasma reactor of FIG. 2 includes a reactor chamber 100 having a grounded conductive cylindrical sidewall 110 and a shaped dielectric ceiling 112, e.g., dome-like. The reactor includes a substrate support electrode 114 for supporting a substrate 116 to be processed in the chamber 100; a cylindrical inductor coil 118 surrounding an upper portion of the chamber beginning near the plane of the top of the substrate 116 or substrate support electrode 114, and extending upwardly therefrom toward the top of the chamber 100; a process gas source 122 and a gas inlet 124, which can be a plurality of inlets spaced about the interior of the chamber 100; and a pump 126 for controlling the chamber pressure. The coil inductor 118 is energized by a plasma source power supply, or RF generator 128, through a conventional active RF match network 130, the top winding of the inductor coil 118 being “hot” and the bottom winding being grounded. The substrate support electrode 114 includes an interior conductive portion 132 connected to a bias RF power supply or generator 134 via a match network 135, and an exterior conductor 136 which is insulated from the interior conductive portion 132. A conductive grounded RF shield 120 surrounds the coil inductor 118.

To carry out the present process, the source power is turned on and one or more processing gases are passed into the chamber 100 from appropriate gas containers (not shown). A fluorocarbon or hydrofluorocarbon processing gas can be used to deposit a polymer onto a patterned photoresist layer to protect the photoresist during the multiple etch steps to follow.

The power to the chamber 100 from the inductive RF power source 128 is suitably from about 200 up to about 3000 watts, and is preferably from about 500 to 2000 watts. The RF source can be a 12.56 MHz power source. No bias power is used during the deposition step. The pressure in the chamber during this step is maintained at about 5 to 300 millitorr.

Suitable fluorocarbon gases include polymer-generating gases such as CH₂F₂, C₄F₆, C₄F₈ and the like. Such gases form a fluorocarbon polytetrafluoroethylene-like coating on the photoresist, protecting it during the following etch steps. The deposition step is generally carried out for about 5 seconds.

The etchant used herein is sulfur hexafluoride (SF). Suitable gas flows of the etchant gas range from 30 to 500 sccm. A small amount of oxygen can also be added. The main etch is carried out with a bias power, e.g., of from 3 to 100 Watts.

The main etch is carried out using a pulsed bias power to the substrate support, using a duty cycle of about 10% to 80%, with a 6 microsecond period. This has remarkably reduced notching, and also improves the uniformity of etching across the substrate.

When the main etch has reached the silicon-silicon oxide interface, an overetch step is begun, which includes a second deposition step to prevent etching of the sidewalls of the opening. Bias power is also used during the overetch step, generally the same amount of power as that used for the main etch step. This bias is also pulsed in the same manner as the main etch step.

The invention will be further described in the following Examples. However, the invention is not to be limited to the details set forth therein.

### EXAMPLE 1

In this Example, the power was maintained at 700 Watts and the pressure was maintained at 18 millitorr; gas flow rates during the deposition and etch steps were increased to 140 sccm and 150 sccm respectively; without adding oxygen. Bias pulsing at a 35% duty cycle and a 6 microsecond period applying 30 watts of bias power was used throughout both the deposition and etch steps. The average bias power delivered was 6 Watts. The average etch depth was 14.8 microns; average silicon etch rate was 1.69 microns/min; average photoresist-silicon selectivity was 20. The notch linewidth measurements in microns are given below:

| | Notch Width, Center | Notch Width, Edge |
|---|---|---|
| 1 micron line | 0.2 | 0.33 |
| 2 micron line | 0.48 | 0.7 |
| 5 micron line | 0.45 | 0.38 |
| 10 micron line | 0.38 | 0.25 |
| 100 micron line | 0.25 | <0.2 |

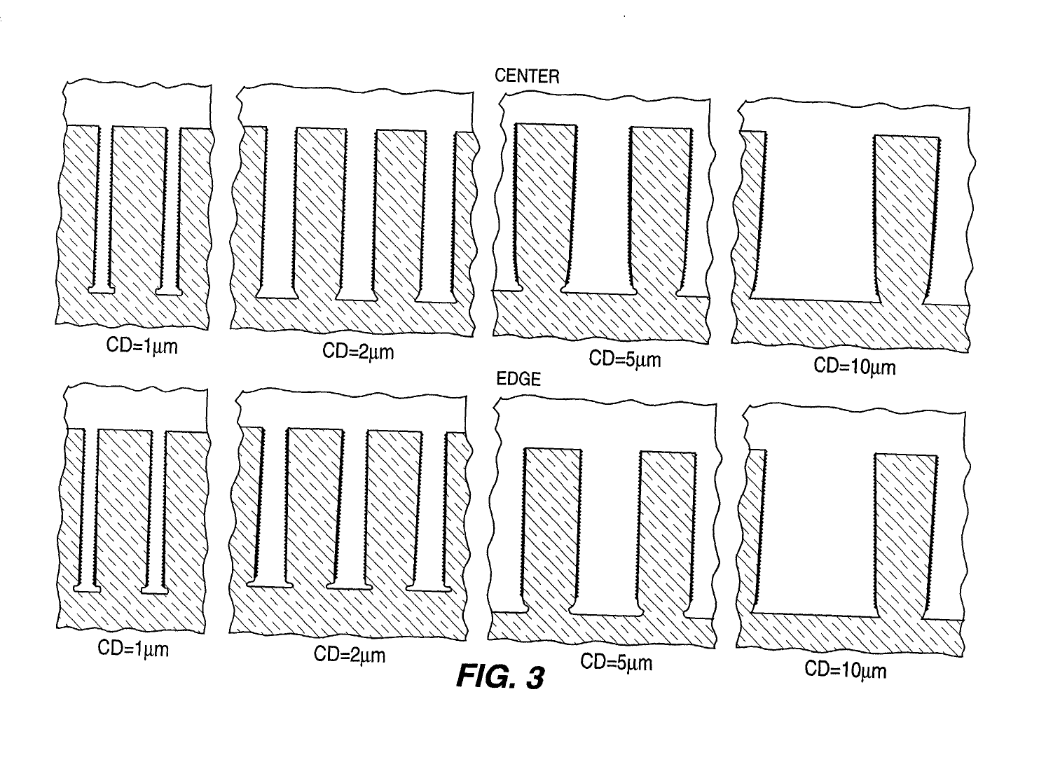

Thus notching was improved, as shown above and in FIG. 3.

### EXAMPLE 2

The etch and overetch steps were carried out as in Example 1 except that the bias power during the deposition steps was almost off, but was held at 20 Watts during the etch and overetch steps. The bias power was pulsed using a duty cycle of 35% and a 6 microsecond period. The average bias power delivered thus was 3.5 Watts.

The above reaction conditions further improved notching, as shown below, and also increased the average photoresist selectivity to 40.7. The average silicon etch rate was 1.24 microns/min.

| | Notch width, Center | Notch Width, Edge |
|---|---|---|
| 1 micron line | <0.2 | 0.28 |
| 2 micron line | <0.2 | <0.2 |
| 5 micron line | <0.2 | <0.2 |
| 10 micron line | <0.2 | <0.2 |
| 100 micron line | <0.2 | <0.2 |

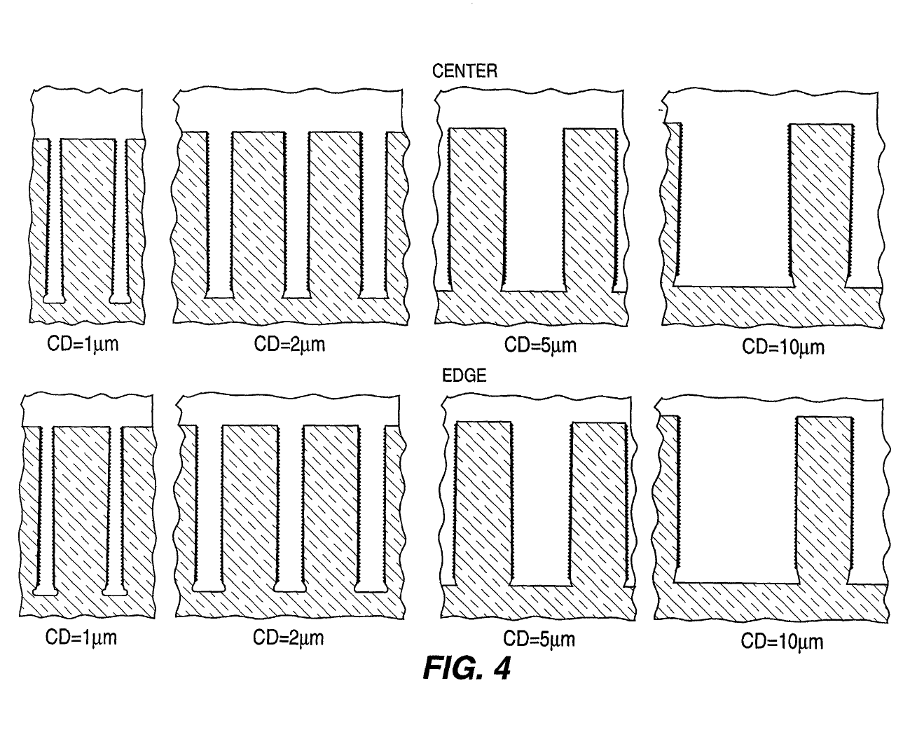

Thus notching was reduced, and made more uniform across the substrate, as further shown in FIG. 4.

### EXAMPLE 3

In this Example, no bias power was used during the deposition steps, but 30 Watts of pulsed bias power was used during the etch steps, again using a duty cycle of 35% and a periof of 6 milliseconds. The average power delivered was 6 Watts.

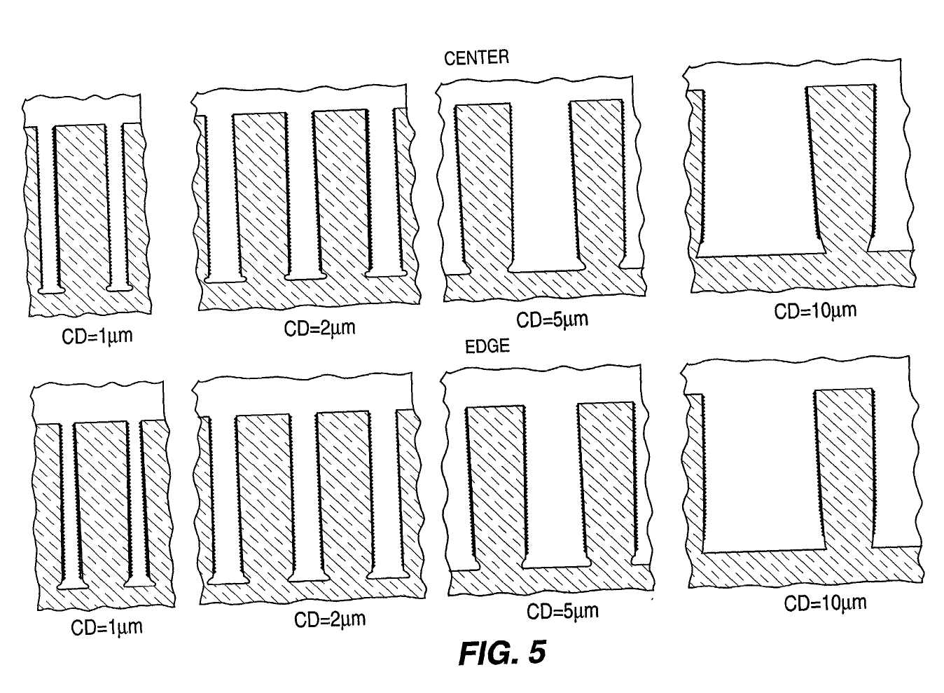

The average depth of etch was 14.9 microns. The average silicon etch rate was higher at 1.56 microns per minute, and average photoresist selectivity was 21.9. Notching was improved, as shown in the data below and in FIG. 5.

| | Notch Width, Center | Notch Width, Edge |
|---|---|---|
| 1 micron line | 0.25 | 0.38 |
| 2 micron line | 0.42 | 0.38 |
| 5 micron line | 0.45 | 0.25 |
| 10 micron line | 0.25 | 0.25 |
| 100 micron line | <0.2 | <0.2 |

The results are also shown in FIG. 5. Notching was improved, but the uniformity of etch across the substrate was not ideal.

### EXAMPLE 4

In this Example, no bias power was used during the deposition steps but 30 Watts of pulsed bias power was used during the etch steps, again using a 35% duty cycle with a period of 6 milliseconds. The average power delivered was 6 Watts.

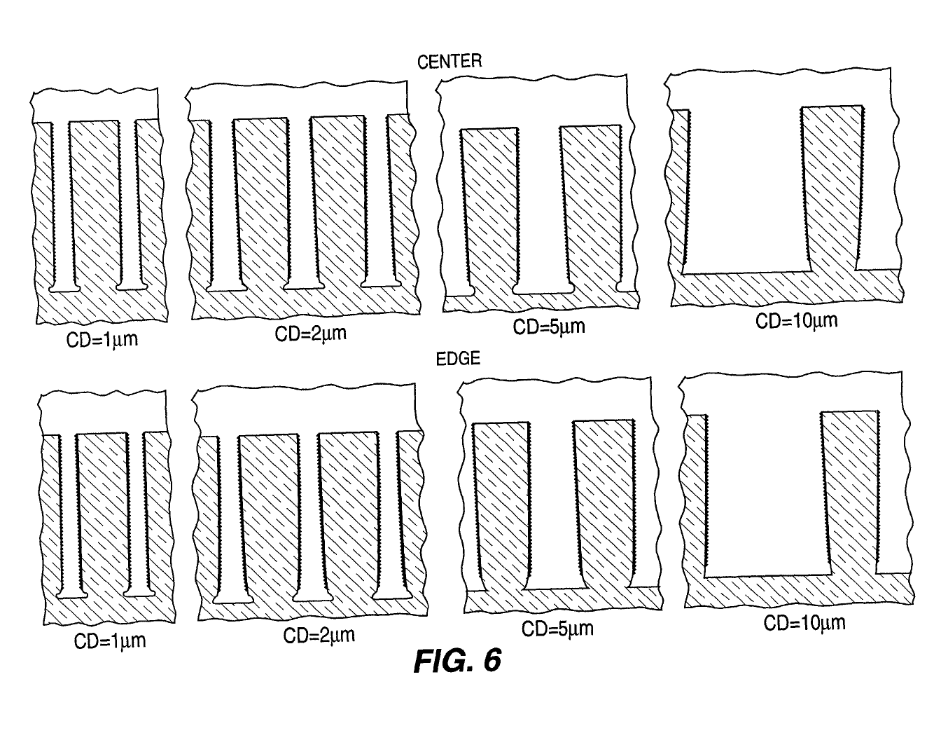

The overetch step was reduced somewhat, so that the average depth of etch was 14.8 microns. The average silicon etch rate was further increased to 1.64; and selectivity was 20.9. Notching was improved, as shown in the data below and in FIG. 6.

| | Notch width, center | Notch Width, Edge |
|---|---|---|
| 1 micron line | <0.2 | <0.2 |
| 2 micron line | 0.25 | 0.25 |
| 5 micron line | <0.2 | <0.2 |
| 10 micron line | <0.2 | <0.2 |
| 100 micron line | <0.2 | <0.2 |

Reference to FIG. 6 shows that notching was further reduced. In addition, improved etch uniformity across the substrate was also achieved, and notching was the same across the substrate.

Although particular etchants, deposition gases, and reaction conditions were illustrated hereinabove, the invention is not meant to be limited by the details described, but only by the scope of the appended claims.

We claim:

1. A method of reducing notching in etched anisotropic openings in silicon over an insulator layer comprising anisotropically etching openings in silicon with a sulfur hexafluoride etchant in a plasma etch chamber fitted with a powered substrate support while bias power is applied to the substrate support electrode during the etch step.

2. A method according to claim 1 wherein the applied bias power to the substrate support electrode is from 3 to 100 Watts.

3. A method according to claim 1 wherein the bias power is pulsed.

4. A method according to claim 3 wherein the pulsed bias power is applied at a duty cycle of 10% to 80% using a 6 microsecond period.

5. A method according to claim 4 wherein the pulsed bias power is applied at a duty cycle of 35%.

6. A method according to claim 1 wherein, prior to etching, a deposition step using a fluorocarbon or hydrofluorocarbon gas is used to deposit a fluorine-containing polymer over the substrate.

7. A method according to claim 1 wherein after the main etch step, overetch deposition and etch steps are carried out to remove debris from the bottom of the opening.

8. A method according to claim 6 wherein no bias power is used during the deposition step.

9. A method according to claim 6 wherein the pressure in the chamber is maintained at about 5 to 300 millitorr during the deposition step.
